(19) United States
(12) Patent Application Publication
(10) Pub. No.: US 2021/0358793 A1
(43) Pub. Date: Nov. 18, 2021

(54) CHIP-CARRYING STRUCTURE, CHIP-PLACING SYSTEM AND CHIP-PLACING METHOD

(71) Applicant: ASTI GLOBAL INC., TAIWAN, Taichung City (TW)

(72) Inventor: Chien-Shou Liao, New Taipei City (TW)

(21) Appl. No.: 17/319,383

(22) Filed: May 13, 2021

(30) Foreign Application Priority Data
May 15, 2020 (TW) 109116144

(51) Int. Cl. H01L 21/683; H01L 21/67; H01L 25/075; H01L 33/62; B25J 15/06

(52) U.S. Cl. CPC H01L 21/6835; H01L 21/67144; H01L 25/0753; H01L 33/62; B23K 2103/56; H01L 2221/68354; H01L 2221/68368; H01L 2933/0066; B25J 15/0616

(57) ABSTRACT

A chip-carrying structure, a chip-placing system and a chip-placing method are provided. The chip-placing method includes providing a chip-carrying structure that includes a removable base and an LED chip separably disposed on the removable base; moving the chip-carrying structure onto at least two conductive materials of a circuit substrate by a chip-carrying device; heating the at least two conductive materials so as to bond the LED chip on the at least two conductive materials; and then removing the removable base from the LED chip that has been bonded on the at least two conductive materials. Therefore, the LED chip can be temporarily carried by the removable base, and the LED chip can be transferred onto the at least two conductive materials by the chip-carrying device.

### CROSS-REFERENCE TO RELATED PATENT APPLICATION

This application claims the benefit of priority to Taiwan Patent Application No. 109116144, filed on May 15, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a carrying structure, a placing system and a placing method, and more particularly to a chip-carrying structure, a chip-placing system and a chip-placing method.

### BACKGROUND OF THE DISCLOSURE

Since a size of a semiconductor chip is becoming smaller and smaller, a miniaturized LED chip will not be captured by a chip-suction nozzle or pushed (such as abutted against) by a chip pin. In addition, when a width of the chip-suction nozzle for capturing the chip or a width of the chip pin for pushing the chip is greater than a distance between two adjacent chips, it would not be possible to use the chip-suction nozzle or the chip pin to transfer another chip onto a position between the two adjacent chips.

### SUMMARY OF THE DISCLOSURE

In response to the above-referenced technical inadequacies, the present disclosure provides a chip-carrying structure, a chip-placing system and a chip-placing method.

In one aspect, the present disclosure provides a chip-carrying structure including a removable base and an LED chip. The removable base includes a convex portion and a concave portion surrounding the convex portion. The LED chip is separably disposed on the convex portion of the removable base. The convex portion has a carrier surface, and a larger area of the carrier surface of the convex portion is covered by the LED chip.

In another aspect, the present disclosure provides a chip-placing system including a substrate-carrying device, a chip-carrying device and a laser-generating device. The substrate-carrying device is used for carrying a circuit substrate. The chip-carrying device is movably disposed above the substrate-carrying device for capturing a chip-carrying structure. The laser-generating device is movably disposed above the substrate-carrying device for generating a laser light beam. The circuit substrate includes at least two conductive pads, and at least two conductive materials are respectively disposed on the at least two conductive pads. The chip-carrying structure includes a removable base and an LED chip separably disposed on the removable base. The chip-carrying structure is moved onto the at least two conductive materials by the chip-carrying device, and the LED chip is electrically connected to the circuit substrate through the at least two conductive materials. The at least two conductive materials are disposed between the LED chip and the circuit substrate, and the at least two conductive materials are heated by the laser light beam generated by the laser-generating device.

In yet another aspect, the present disclosure provides a chip-placing method, including: providing a chip-carrying structure that includes a removable base and an LED chip separably disposed on the removable base; moving the chip-carrying structure onto a circuit substrate by a chip-carrying device, in which at least two conductive materials are disposed between the LED chip and the circuit substrate, and the LED chip is electrically connected to the circuit substrate through the at least two conductive materials; heating the at least two conductive materials so as to bond the LED chip on the at least two conductive materials; and then removing the removable base from the LED chip that has been bonded on the at least two conductive materials.

Therefore, by virtue of “the LED chip being separably disposed on the convex portion of the removable base”, the LED chip can be temporarily carried by the removable base.

Furthermore, by virtue of “the chip-carrying structure including a removable base and an LED chip separably disposed on the removable base” and “the chip-carrying structure being moved onto the at least two conductive materials by the chip-carrying device”, the LED chip can be temporarily carried by the removable base, and the LED chip can be transferred onto the at least two conductive materials by the chip-carrying device.

Furthermore, by virtue of “providing a chip-carrying structure that includes a removable base and an LED chip separably disposed on the removable base” and “moving the chip-carrying structure onto a circuit substrate by a chip-carrying device”, the LED chip can be temporarily carried by the removable base, and the LED chip can be transferred onto the at least two conductive materials by the chip-carrying device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a chip-placing method according to the present disclosure.

FIG. 2 is a schematic view of step S200 of the chip-placing method according to a first embodiment of the present disclosure.

FIG. 3 is a schematic view of step S202 of the chip-placing method according to the first embodiment of the present disclosure.

FIG. 4 is a schematic view of step S204 of the chip-placing method according to the first embodiment of the present disclosure.

FIG. 5 is a schematic view of step S206 and step S208 of the chip-placing method according to the first embodiment of the present disclosure.

FIG. 6 is a schematic view of step S210 of the chip-placing method according to the first embodiment of the present disclosure.

FIG. 7 is a schematic view of step S212 of the chip-placing method according to the first embodiment of the present disclosure.

FIG. 8 is a schematic view of step S214 of the chip-placing method according to the first embodiment of the present disclosure.

FIG. 9 is a schematic view of step S216 of the chip-placing method according to the first embodiment of the present disclosure.

FIG. 10 is a schematic view of an LED display device according to the first embodiment of the present disclosure.

FIG. 11 is a schematic view of a removable base being removed from an LED chip by a semiconductor process according to the first embodiment of the present disclosure.

FIG. 12 is a schematic view of step S300 of the chip-placing method according to a second embodiment of the present disclosure.

FIG. 13 is a schematic view of step S302 and step S304 of the chip-placing method according to the second embodiment of the present disclosure.

FIG. 14 is a schematic view of step S306 of the chip-placing method according to the second embodiment of the present disclosure.

FIG. 15 is a schematic view of a chip-placing method for projecting a laser light beam generated by a laser-generating device onto a connection interface between the removable base and each initial LED chip according to a third embodiment of the present disclosure.

FIG. 16 is a schematic view of a chip-placing method for projecting a laser light beam generated by a laser-generating device onto a connection interface between the removable base and each initial LED chip according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

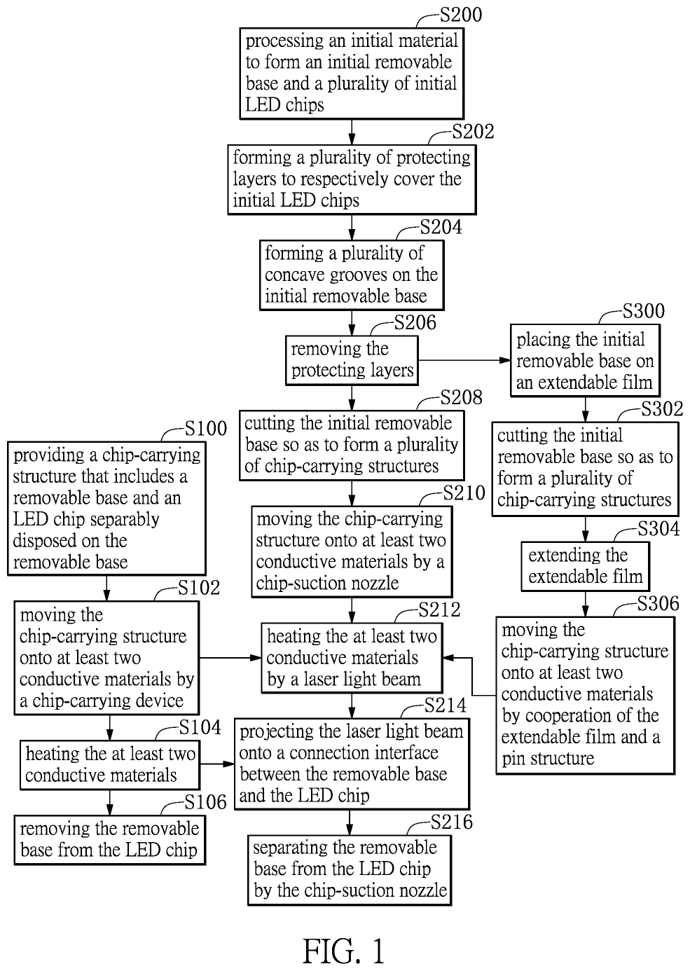

Referring to FIG. 1 to FIG. 16, the present disclosure provides a chip-carrying structure S including a removable base 1 and an LED (light-emitting diode) chip 2. The removable base 1 includes a convex portion 11 (or a protrusion portion) and a concave portion 12 surrounding the convex portion 11. The LED chip 2 is separably disposed on the convex portion 11 of the removable base 1. The convex portion 11 has a carrier surface 1100, and a larger area of the carrier surface 1100 of the convex portion 11 is covered by the LED chip 2.

Referring to FIG. 1 to FIG. 16, the present disclosure provides a chip-placing system, including a substrate-carrying device D, a chip-carrying device C and a laser-generating device L. The substrate-carrying device D can be used for carrying a circuit substrate P. The chip-carrying device C is movably disposed above the substrate-carrying device D for capturing (or suctioning) a chip-carrying structure S. The laser-generating device L is movably disposed above the substrate-carrying device D for generating a laser light beam L100. The circuit substrate P includes at least two conductive pads P100, and at least two conductive materials M are respectively disposed on the at least two conductive pads P100. The chip-carrying structure S includes a removable base 1 and an LED chip 2 separably disposed on the removable base 1. The chip-carrying structure S is moved onto the at least two conductive materials M by the chip-carrying device C, and the LED chip 2 is electrically connected to the circuit substrate P through the at least two conductive materials M. The at least two conductive materials M are disposed between the LED chip 2 and the circuit substrate P, and the at least two conductive materials M are heated (or cured) by the laser light beam L100 generated by the laser-generating device L.

Referring to FIG. 1 to FIG. 16, the present disclosure provides a chip-placing method, including: firstly, providing a chip-carrying structure S that includes a removable base 1 and an LED chip 2 separably disposed on the removable base 1 (step S100); next, moving the chip-carrying structure S onto at least two conductive materials M of a circuit substrate P by a chip-carrying device C, in which the LED chip 2 is electrically connected to the circuit substrate P through the at least two conductive materials M (step S102);

afterwards, heating the at least two conductive materials M so as to bond the LED chip 2 on the at least two conductive materials M (step S104); and then removing the removable base 1 from the LED chip 2 that has been bonded on the at least two conductive materials M (that is to say, the LED chip 2 remains on the at least two conductive materials M) (step S106).

### First Embodiment

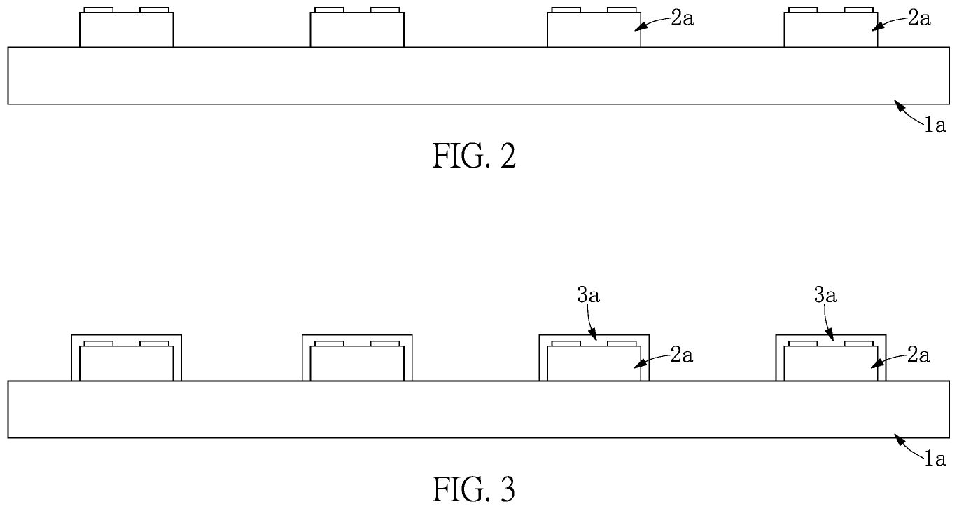

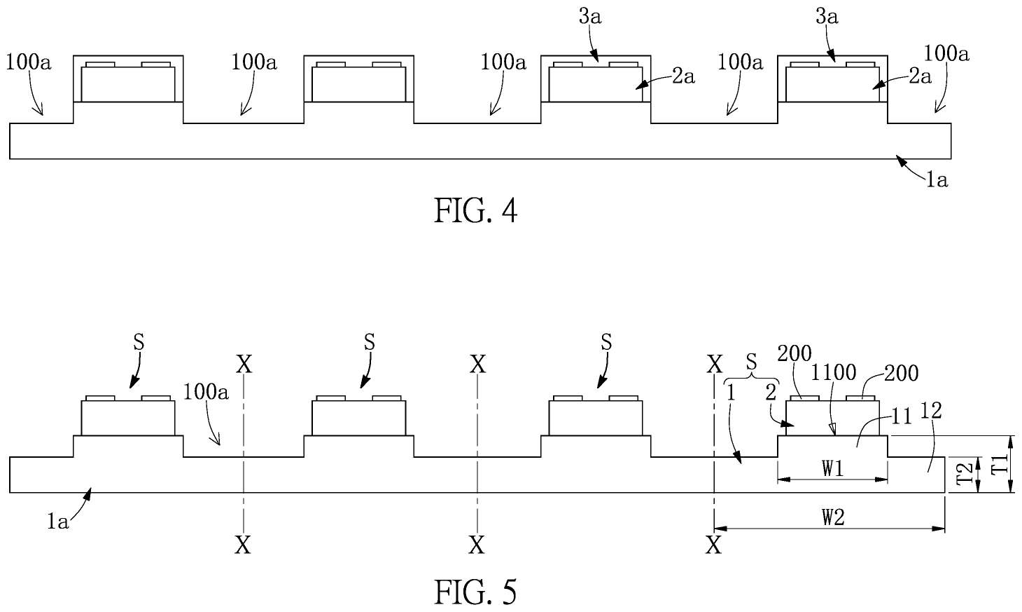

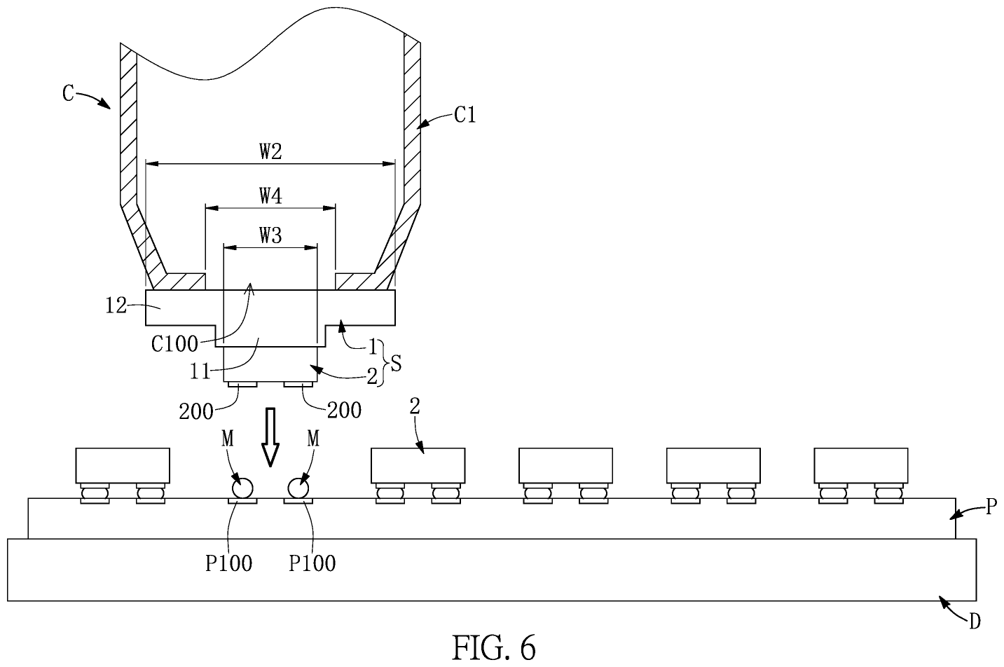

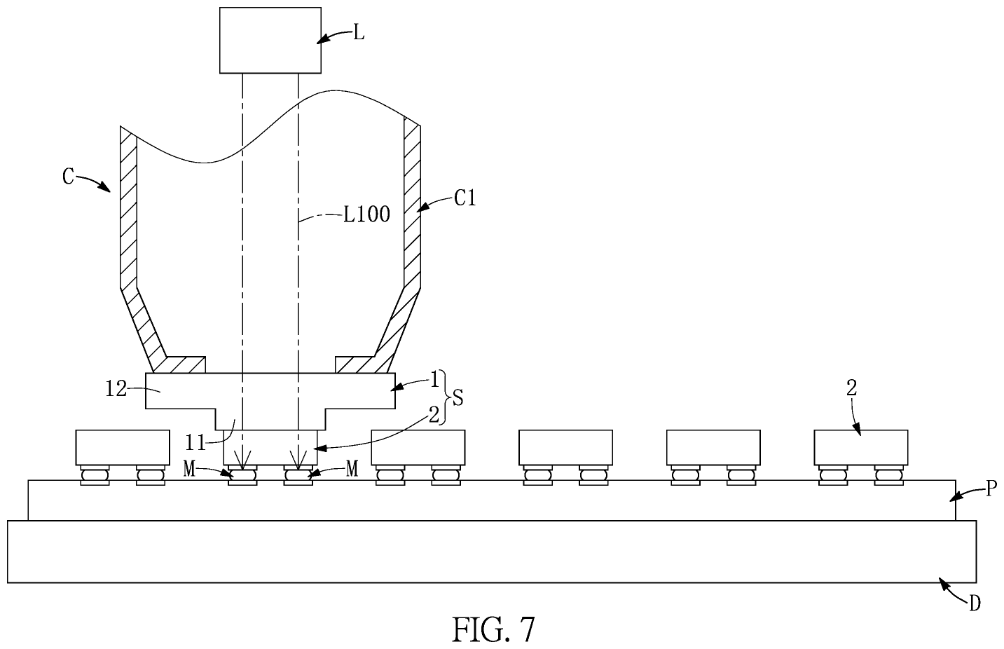

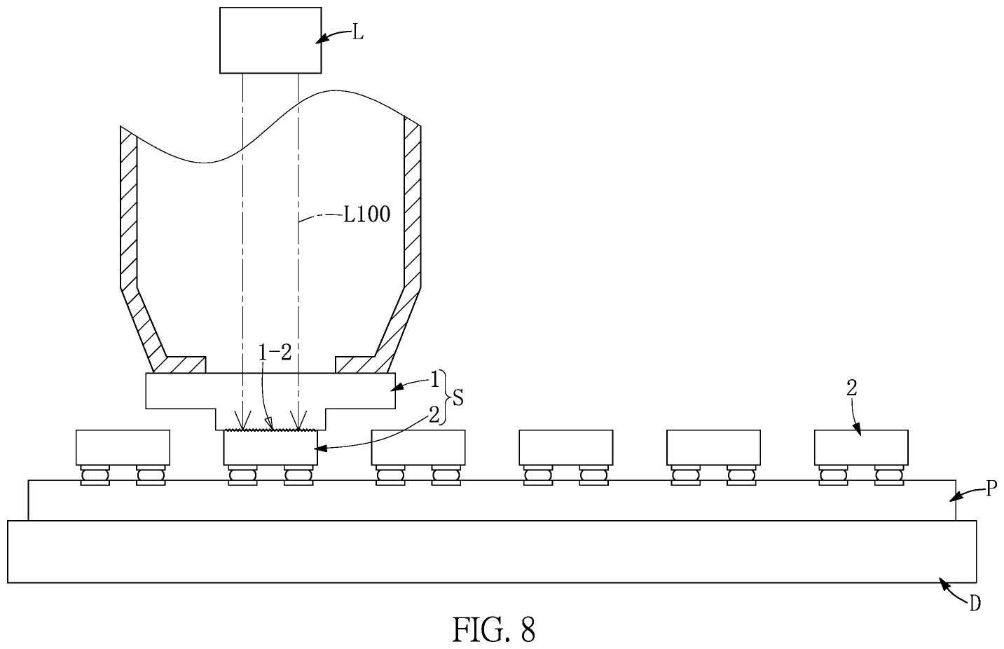

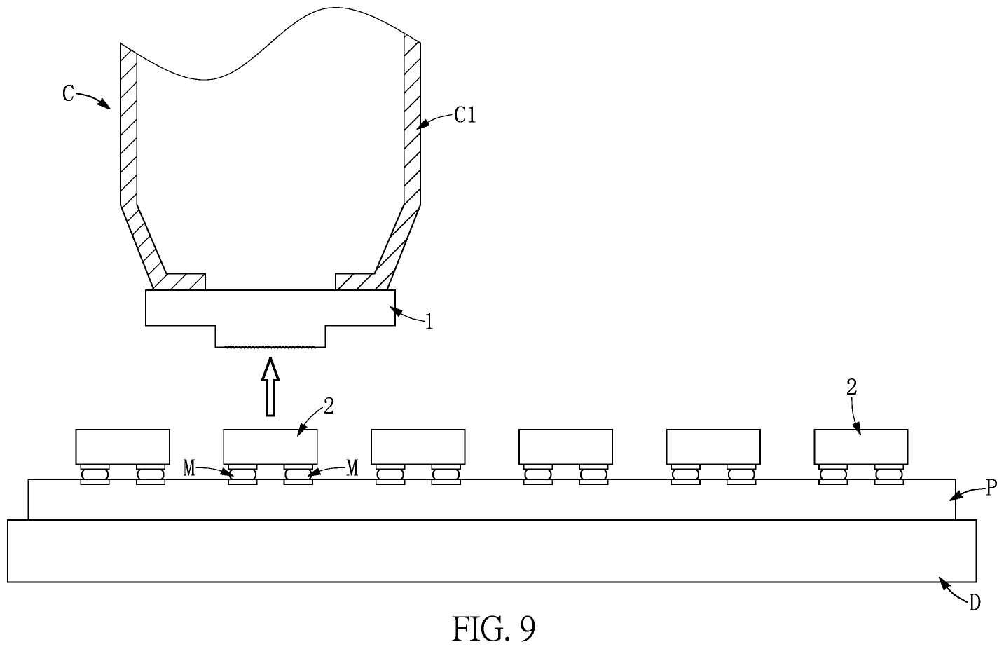

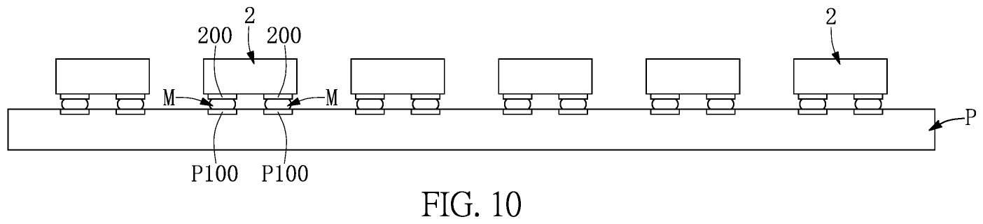

Referring to FIG. 1 to FIG. 10, a first embodiment of the present disclosure provides a chip-placing method, including: firstly, referring to FIG. 1 and FIG. 2, processing an initial material (such as a wafer or any semiconductor material, not shown in figures) to form an initial removable base 1a and a plurality of initial LED chips 2a disposed on the initial removable base 1a (step S200); next, referring to FIG. 1 and FIG. 3, forming a plurality of protecting layers 3a on the initial removable base 1a to respectively cover the initial LED chips 2a (step S202); afterwards, referring to FIG. 1 and FIG. 4, forming a plurality of concave grooves 100a (such as concave regions) that are disposed on the initial removable base 1a and not covered by the protecting layers 3a (step S204); thereafter, referring to FIG. 1 and FIG. 5, removing the protecting layers 3a (step S206); next, referring to FIG. 1 and FIG. 5, cutting the initial removable base 1a having the concave grooves 100a along a cutting line X-X so as to form a plurality of chip-carrying structures S (i.e., a plurality of chip-carrying units) (step S208); afterwards, referring to FIG. 1 and FIG. 6, transferring (or moving) the chip-carrying structure S onto at least two conductive materials M of a circuit substrate P by a chip-suction nozzle C1 of a chip-carrying device C (due to the suction of the chip-suction nozzle C1) (step S210); thereafter, referring to FIG. 1 and FIG. 7, heating (or curing or baking) the at least two conductive materials M by a laser light beam L100 with a predetermined wavelength that is generated by a laser-generating device L so as to bond (or fix) the LED chip 2 on the at least two conductive materials M (step S212); next, referring to FIG. 1 and FIG. 8, projecting the laser light beam L100 (having an adjustable wavelength) generated by the laser-generating device L onto a connection interface (1-2) between the removable base 1 and the LED chip 2 so as to decrease a bonding strength between the removable base 1 and each of the LED chips 2 (step S214); afterwards, referring to FIG. 1, FIG. 9 and FIG. 10, separating the removable base 1 from the LED chip 2 by the chip-suction nozzle C1 of the chip-carrying device C, so that the LED chip 2 that has been bonded on the at least two conductive materials M is remained (such as for repairing a vacant position of a bad LED chip) (step S216). However, the aforementioned description is merely an example and is not meant to limit the scope of the present disclosure.

For example, referring to FIG. 5 and FIG. 6, the chip-carrying structure S includes a removable base 1 and an LED chip 2 separably disposed on the removable base 1. More particularly, the removable base 1 includes a convex portion 11 and a concave portion 12 surrounding the convex portion 11, and the LED chip 2 is separably disposed on the convex portion 11 of the removable base 1. In addition, the convex portion 11 has a carrier surface 1100, and a larger area (such as over 50% or 80%) of the carrier surface 1100 of the convex portion 11 is covered by the LED chip 2, so that only one LED chip 2 can be separably disposed on the convex portion 11 of the removable base 1. Moreover, the LED chip 2 includes at least two chip pads 200 disposed on a top surface thereof, and the at least two chip pads 200 are separated and insulated from the removable base 1. It should be noted that in FIG. 5, a thickness T1 of the convex portion 11 is larger than a thickness T2 of the concave portion 12, and a width W1 of the convex portion 11 is smaller than a width W2 of the concave portion 12. Furthermore, as shown in FIG. 6, a width W3 of a bottom surface of the LED chip 2 is smaller than a width W4 of a chip-suction opening C100 of the chip-suction nozzle C1, so that the LED chip 2 cannot be captured or suctioned by the chip-suction opening C100 of the chip-suction nozzle C1 (i.e., the chip-suction opening C100 of the chip-suction nozzle C1 cannot be completely covered or enclosed by the LED chip 2). In addition, as shown in FIG. 6, a width W2 of a bottom surface of the removable base 1 (such as the width W2 of the concave portion 12 of the removable base 1) is greater than the width W4 of the chip-suction opening C100 of the chip-suction nozzle C1, so that the removable base 1 can be directly captured or suctioned by the chip-suction opening C100 of the chip-suction nozzle C1 (i.e., the chip-suction opening C100 of the chip-suction nozzle C1 can be completely covered or enclosed by the removable base 1). Therefore, the LED chip 2 can be indirectly carried by the chip-suction opening C100 of the chip-suction nozzle C1 due to the removable base 1. However, the aforementioned description is merely an example and is not meant to limit the scope of the present disclosure.

For example, the conductive material M may be a solder ball, solder paste or any other kind of solder material. In addition, according to different requirements, the at least two conductive materials M can be respectively disposed on the at least two conductive pads P100 in advance (as shown in FIG. 6), or the at least two conductive materials M can be respectively disposed on at least two chip pads 200 of the LED chip 2 in advance. Referring to FIG. 7, after the at least two conductive materials M are heated and solidified by the laser light beam L100 generated by the laser-generating device L, the LED chip 2 can be electrically connected to the circuit substrate P through the at least two conductive materials M. However, the aforementioned description is merely an example and is not meant to limit the scope of the present disclosure.

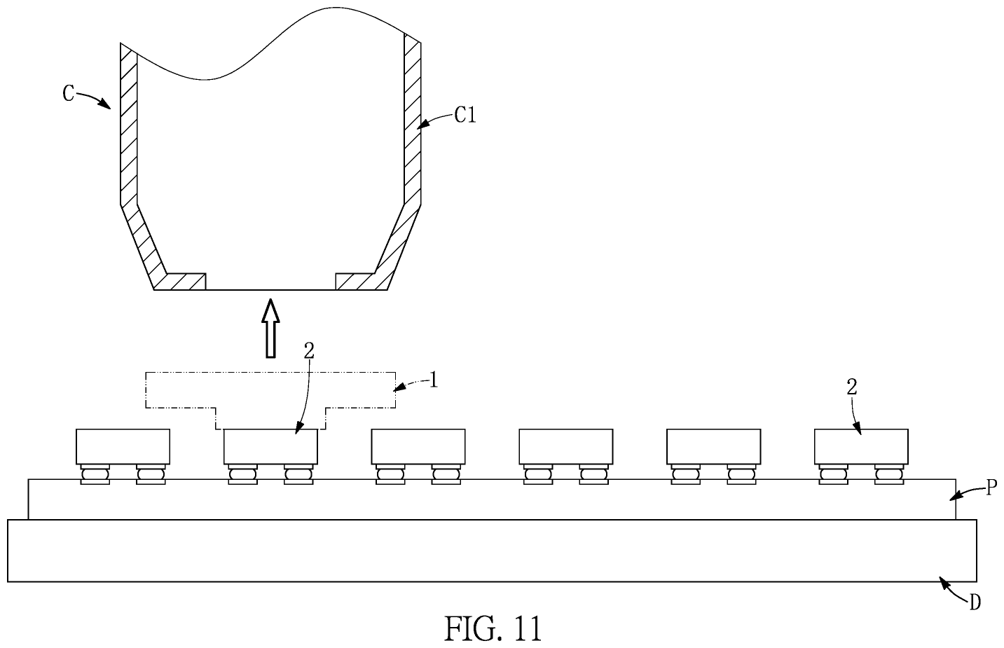

For example, referring to FIG. 7 and FIG. 11, after the at least two conductive materials M are heated and solidified by the laser light beam L100 generated by the laser-generating device L (as shown in FIG. 7), the chip-suction nozzle C1 of the chip-carrying device C can be separated from the removable base 1 in advance, and then the removable base 1 can be removed from the LED chip 2 by a semiconductor process (such as exposing and developing, etc.) (as shown in FIG. 11). That is to say, according to different requirements, the removable base 1 can be removed from the LED chip 2 by cooperation of the laser-generating device L (such as the laser light beam L100) and the chip-carrying device C (such as the chip-suction nozzle C1) (as shown in FIG. 8 and FIG. 9), or the removable base 1 can also be directly removed from the LED chip 2 by a semiconductor process (as shown in FIG. 11). However, the aforementioned description is merely an example and is not meant to limit the scope of the present disclosure.

It should be noted that in the FIG. 7, a width of a bottommost side of the chip-suction nozzle C1 is greater than a distance between two adjacent LED chips 2 that are disposed on the circuit substrate P. As a result, if the chip-suction nozzle C1 is moved to place another LED chip 2 without the removable base 1 onto the circuit substrate P and between the two adjacent LED chips 2, the chip-suction nozzle C1 will collide with the two adjacent LED chips 2.

### Second Embodiment

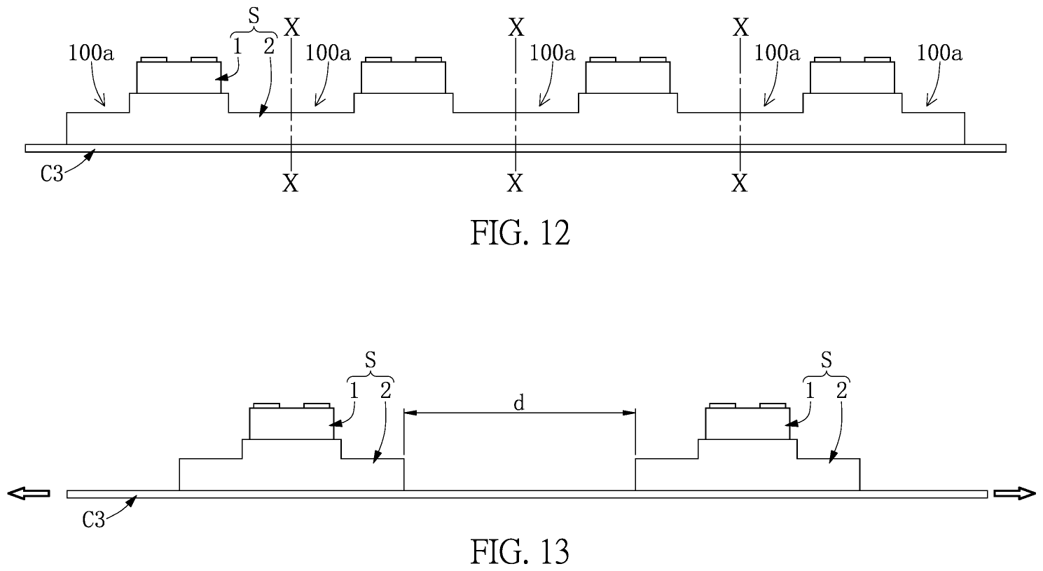

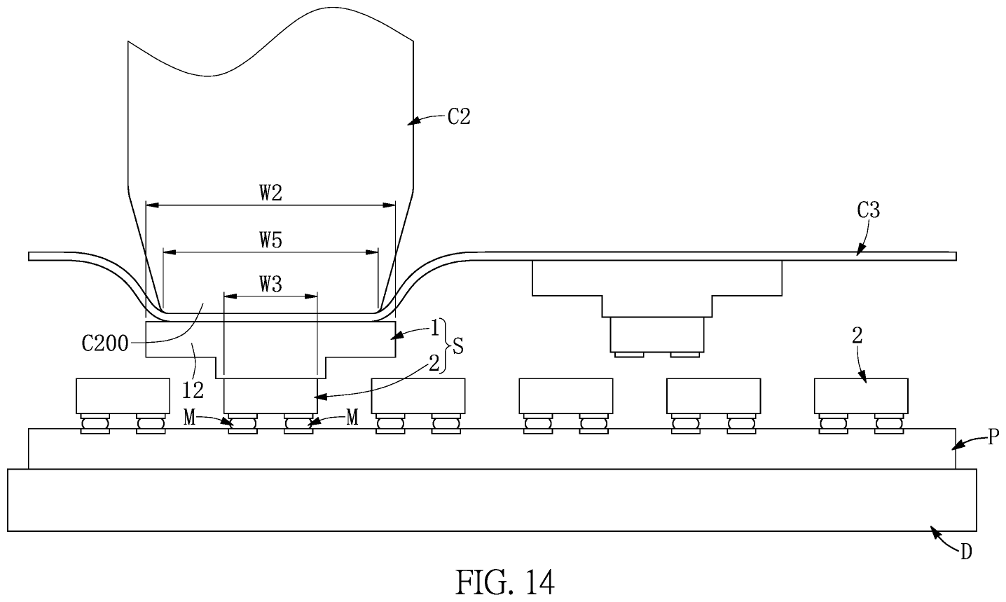

Referring to FIG. 1 to FIG. 5 and FIG. 12 to FIG. 14, a second embodiment of the present disclosure provides a chip-placing method. The difference between the chip-placing method of the second embodiment and the chip-placing method of the first embodiment is as follows. The chip-placing method of the second embodiment includes: referring to FIG. 1 and FIG. 12, placing the initial removable base 1a having the concave grooves 100a on an extendable film C3 (or an expandable film) of the chip-carrying device C (step S300); next, referring to FIG. 1 and FIG. 12, cutting the initial removable base 1a having the concave grooves 100a along a cutting line X-X so as to form a plurality of chip-carrying structures S (i.e., a plurality of chip-carrying units) (step S302); afterwards, referring to FIG. 1 and FIG. 13, extending the extendable film C3 so as to increase a distance d between any two of the chip-carrying structures S (step S304); and then referring to FIG. 1 and FIG. 14, moving the chip-carrying structure S onto at least two conductive materials M of a circuit substrate P by cooperation of the extendable film C3 (such as a blue film for carrying the chip-carrying structure S) and a pin structure C2 (such as a chip pin for contacting and pushing the chip-carrying structure S) (step S306). However, the aforementioned description is merely an example and is not meant to limit the scope of the present disclosure.

For example, referring to FIG. 14, a width W3 of a bottom surface of the LED chip 2 is smaller than a width W5 of a bottom side of a pin portion C200 of the pin structure C2, and a width W2 of a bottom surface of the removable base 1 (such as the width W2 of the concave portion 12 of the removable base 1) is greater than the width W5 of the bottom side of the pin portion C200 of the pin structure C2. However, the aforementioned description is merely an example and is not meant to limit the scope of the present disclosure.

It should be noted that the chip-carrying device C includes a chip-suction nozzle C1 (as shown in the first embodiment) or an extendable film C3 matched with a pin structure C2 (as shown in the second embodiment), and the chip-carrying structure S can be captured or suctioned by the chip-suction nozzle C1 (as shown in the first embodiment) or can be adhered by the extendable film C3 and pushed by the pin structure C2 (as shown in the second embodiment).

It should be noted that in the FIG. 14, the width W5 of the bottom side of the pin portion C200 of the pin structure C2 is greater than a distance between two adjacent LED chips 2 that are disposed on the circuit substrate P. As a result, if the pin portion C200 of the pin structure C2 is moved to downwardly push another LED chip 2 without the removable base 1 onto the circuit substrate P and between the two adjacent LED chips 2, the pin portion C200 of the pin structure C2 will collide with the two adjacent LED chips 2.

### Third Embodiment

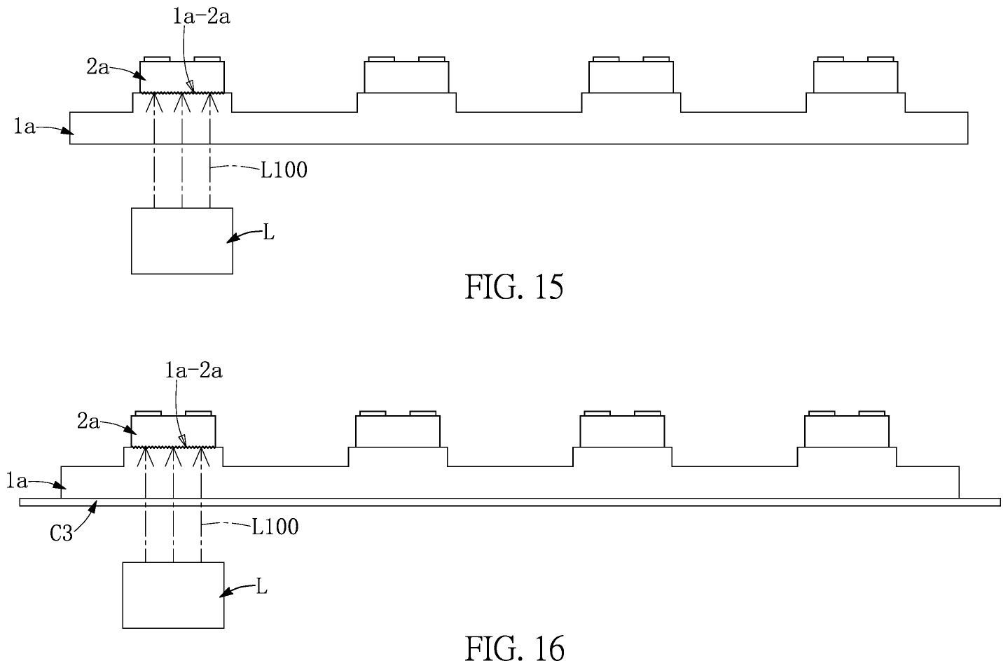

Referring to FIG. 15, a third embodiment of the present disclosure provides a chip-placing method. The difference between the chip-placing method of the third embodiment and the chip-placing method of the first embodiment is as follows. Before the step S208 of cutting the initial removable base 1a having the concave grooves 100a, the chip-placing method of the third embodiment further includes: projecting a laser light beam L100 generated by a laser-generating device L onto a connection interface (1a-2a) (such as residual gallium) between the initial removable base 1a (having a gallium material) and the initial LED chip 2a (such as each of the initial LED chips 2a) so as to decrease a bonding strength between the initial removable base 1a and the initial LED chip 2a (for example, the initial removable base 1a and the initial LED chip 2a can be connected with each other by the residual gallium). Hence, before projecting the laser light beam L100, the initial removable base 1a and each initial LED chip 2a can be connected with each other through a gallium material. That is to say, before projecting the laser light beam L100, the removable base 1 and the LED chip 2 can be connected with each other through the gallium material. Therefore, in the step S106 of removing the removable base 1, the chip-placing method of the third embodiment further includes: separating the removable base 1 from the LED chip 2 by a chip-suction nozzle C1 of the chip-carrying device C.

### Fourth Embodiment

Referring to FIG. 16, a fourth embodiment of the present disclosure provides a chip-placing method. The difference between the chip-placing method of the fourth embodiment and the chip-placing method of the second embodiment is as follows. Before the step S300 of cutting the initial removable base 1a having the concave grooves 100a, the chip-placing method of the fourth embodiment further includes: projecting a laser light beam L100 generated by a laser-generating device L onto a connection interface (1a-2a) (such as residual gallium) between the initial removable base 1a (having a gallium material) and the initial LED chip 2a (such as each of the initial LED chips 2a) so as to decrease a bonding strength between the initial removable base 1a and the initial LED chip 2a (for example, the initial removable base 1a and the initial LED chip 2a can be connected with each other by the residual gallium). Hence, before projecting the laser light beam L100, the initial removable base 1a and each initial LED chip 2a can be connected with each other through a gallium material. That is to say, before projecting the laser light beam L100, the removable base 1 and the LED chip 2 can be connected with each other through the gallium material. Therefore, in the step S106 of removing the removable base 1, the chip-placing method of the fourth embodiment further includes: separating the removable base 1 from the LED chip 2 by a chip-suction nozzle C1 of the chip-carrying device C.

### Beneficial Effects of Embodiments

In conclusion, by virtue of “the LED chip 2 being separably disposed on the convex portion 11 of the removable base 1”, the LED chip 2 can be temporarily carried by the removable base 1.

Furthermore, by virtue of “the chip-carrying structure S including a removable base 1 and an LED chip 2 separably disposed on the removable base 1” and “the chip-carrying structure S being moved onto the at least two conductive materials M by the chip-carrying device C”, the LED chip 2 can be temporarily carried by the removable base 1, and the LED chip 2 can be transferred onto the at least two conductive materials M by the chip-carrying device C.

Furthermore, by virtue of “providing a chip-carrying structure S that includes a removable base 1 and an LED chip 2 separably disposed on the removable base 1” and “moving the chip-carrying structure S onto a circuit substrate P by a chip-carrying device C”, the LED chip 2 can be temporarily carried by the removable base 1, and the LED chip 2 can be transferred onto the at least two conductive materials M by the chip-carrying device C.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip-carrying structure, comprising:
a removable base including a convex portion and a concave portion surrounding the convex portion; and
an LED chip separably disposed on the convex portion of the removable base;
wherein the convex portion has a carrier surface, and a larger area of the carrier surface of the convex portion is covered by the LED chip;
wherein the removable base and the LED chip are connected with each other through a gallium material.

2. The chip-carrying structure according to claim 1, wherein only the LED chip is separably disposed on the convex portion of the removable base.

3. The chip-carrying structure according to claim 1, wherein the LED chip includes at least two chip pads disposed on a top surface thereof, and the at least two chip pads are separated and insulated from the removable base.

4. The chip-carrying structure according to claim 1, wherein a thickness of the convex portion is larger than a thickness of the concave portion, and a width of the convex portion is smaller than a width of the concave portion.

5. The chip-carrying structure according to claim 1, wherein a width of a bottom surface of the LED chip is smaller than a width of a chip-suction opening of a chip-suction nozzle or a width of a bottom side of a pin portion of a pin structure, and a width of a bottom surface of the removable base is greater than the width of the chip-suction opening of the chip-suction nozzle or the width of the bottom side of the pin portion of the pin structure.

6. A chip-placing system, comprising:
a substrate-carrying device for carrying a circuit substrate;
a chip-carrying device movably disposed above the substrate-carrying device for capturing a chip-carrying structure; and
a laser-generating device movably disposed above the substrate-carrying device for generating a laser light beam;
wherein the circuit substrate includes at least two conductive pads;
wherein the chip-carrying structure includes a removable base and an LED chip separably disposed on the removable base, and the removable base and the LED chip are connected with each other through a gallium material;
wherein the chip-carrying structure is moved onto the circuit substrate;
wherein at least two conductive materials are disposed between the LED chip and the circuit substrate, and the at least two conductive materials are heated by the laser light beam generated by the laser-generating device.

7. The chip-placing system according to claim 6, wherein the chip-carrying device includes a chip-suction nozzle or a cooperating assembly including an extendable film and a pin structure, and the chip-carrying structure is captured by the chip-suction nozzle or adhered by the extendable film.

8. The chip-placing system according to claim 6, wherein the removable base includes a convex portion and a concave portion surrounding the convex portion, and the LED chip is separably disposed on the convex portion of the removable base.

9. The chip-placing system according to claim 8, wherein the convex portion has a carrier surface, and a larger area of the carrier surface of the convex portion is covered by the LED chip.

10. The chip-placing system according to claim 8, wherein a thickness of the convex portion is larger than a thickness of the concave portion, and a width of the convex portion is smaller than a width of the concave portion.

11. The chip-placing system according to claim 6, wherein the LED chip includes at least two chip pads disposed on a top surface thereof, and the at least two chip pads are separated and insulated from the removable base.

12. The chip-placing system according to claim 6, wherein a width of a bottom surface of the LED chip is smaller than a width of a chip-suction opening of a chip-suction nozzle or a width of a bottom side of a pin portion of a pin structure, and a width of a bottom surface of the removable base is greater than the width of the chip-suction opening of the chip-suction nozzle or the width of the bottom side of the pin portion of the pin structure.

13. A chip-placing method, comprising:
providing a chip-carrying structure that includes a removable base and an LED chip separably disposed on the removable base, wherein the removable base and the LED chip are connected with each other through a gallium material;
moving the chip-carrying structure onto a circuit substrate, wherein at least two conductive materials are disposed between the LED chip and the circuit substrate, and the LED chip is electrically connected to the circuit substrate through the at least two conductive materials;
heating the at least two conductive materials so as to bond the LED chip on the at least two conductive materials; and
removing the removable base from the LED chip that has been bonded on the at least two conductive materials.

14. The chip-placing method according to claim 13, wherein the step of providing the chip-carrying structure further comprises:
processing an initial material to form an initial removable base and a plurality of initial LED chips disposed on the initial removable base;
forming a plurality of protecting layers on the initial removable base to respectively cover the initial LED chips;
forming a plurality of concave grooves that are disposed on the initial removable base and not covered by the protecting layers;
removing the protecting layers; and
cutting the initial removable base having the concave grooves so as to form a plurality of chip-carrying units that each serve as the chip-carrying structure.

15. The chip-placing method according to claim 14, wherein before the step of cutting the initial removable base having the concave grooves, the method further comprises: decreasing a bonding strength between the initial removable base and the initial LED chip; wherein the step of removing the removable base further comprises: separating the removable base from the LED chip.

16. The chip-placing method according to claim 14, wherein the removable base includes a convex portion and a concave portion surrounding the convex portion, and the LED chip is separably disposed on the convex portion of the removable base; wherein the convex portion has a carrier surface, and a larger area of the carrier surface of the convex portion is covered by the LED chip; wherein a thickness of the convex portion is larger than a thickness of the concave portion, and a width of the convex portion is smaller than a width of the concave portion; wherein a width of a bottom surface of the LED chip is smaller than a width of a chip-suction opening of the chip-suction nozzle or a width of a bottom side of a pin portion of a pin structure, and a width of a bottom surface of the removable base is greater than the width of the chip-suction opening of the chip-suction nozzle or the width of the bottom side of the pin portion of the pin structure.

17. The chip-placing method according to claim 13, wherein the step of providing the chip-carrying structure further comprises:
processing an initial material to form an initial removable base and a plurality of initial LED chips disposed on the initial removable base;
forming a plurality of protecting layers on the initial removable base to respectively cover the initial LED chips;
forming a plurality of concave grooves that are disposed on the initial removable base and not covered by the protecting layers;
removing the protecting layers;
placing the initial removable base having the concave grooves on an extendable film;
cutting the initial removable base having the concave grooves so as to form a plurality of chip-carrying units; and
extending the extendable film so as to increase a distance between any two of the chip-carrying units that each serve as the chip-carrying structure;
wherein the chip-carrying structure is moved onto the at least two conductive materials of the circuit substrate by cooperation of the extendable film and a pin structure.

18. The chip-placing method according to claim 17, wherein before the step of cutting the initial removable base having the concave grooves, the method further comprises: decreasing a bonding strength between the initial removable base and the initial LED chip; wherein the step of removing the removable base further comprises: separating the removable base from the LED chip.

19. The chip-placing method according to claim 17, wherein the removable base includes a convex portion and a concave portion surrounding the convex portion, and the LED chip is separably disposed on the convex portion of the removable base; wherein the convex portion has a carrier surface, and a larger area of the carrier surface of the convex portion is covered by the LED chip; wherein a thickness of the convex portion is larger than a thickness of the concave portion, and a width of the convex portion is smaller than a width of the concave portion; wherein a width of a bottom surface of the LED chip is smaller than a width of a chip-suction opening of the chip-suction nozzle or a width of a bottom side of a pin portion of the pin structure, and a width of a bottom surface of the removable base is greater than the width of the chip-suction opening of the chip-suction nozzle or the width of the bottom side of the pin portion of the pin structure.

20. The chip-placing method according to claim 13, wherein the step of removing the removable base further comprises:
decreasing a bonding strength between the removable base and the LED chip; and
separating the removable base from the LED chip.
